(19) United States
(12) Patent Application Publication
(10) Pub. No.: US 2010/0147377 A1
(43) Pub. Date: Jun. 17, 2010

(54) SOLAR CELL MODULE AND METHOD FOR PRODUCING THE SAME

(76) Inventors: Seiji ISHIHARA, Osaka-shi (JP); Hiroyuki Nakanishi, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/635,031

(22) Filed: Dec. 10, 2009

(30) Foreign Application Priority Data
Dec. 11, 2008 (JP) 2008-315751

(51) Int. Cl. H01L 31/0203; H01L 31/18

(52) U.S. Cl. 136/256; 438/64; 257/E21.502; 257/E31.117

(57) ABSTRACT

An object of the present invention is to provide a solar cell module in which a solar cell element connected with a substrate by wire bonding is sealed and which is capable of preventing deformation of a bonding wire. For this object, the solar cell module of the present invention is designed such that the bonding wire is sealed with potting resin so that a surface of the solar cell element, which surface is opposite to the substrate, is exposed.

This Nonprovisional application claims priority under 35 U.S.C. §119(a) on Patent Application No. 2008-315751 filed in Japan on Dec. 11, 2008, the entire contents of which are hereby incorporated by reference.

### TECHNICAL FIELD

The present invention relates to a solar cell module produced by sealing a solar cell element connected with (mounted on) a substrate by wire bonding, and to a method for producing the solar cell module.

### BACKGROUND ART

A conventional technique for sealing a solar cell element connected with (mounted on) a substrate by wire bonding is a technique for coating the solar cell element with epoxy resin by use of a mold and sealing the solar cell element.

However, since the conventional technique requires a mold, it is difficult to carry out the technique at low costs. Further, since it is impossible to seal a plurality of solar cell elements together by the technique, the technique is inappropriate for mass production of solar cell modules. Further, in the technique, epoxy resin is poured into a mold and then the epoxy resin is taken out of the mold by use of curing and contraction of the epoxy resin at the time of molding, but the technique suffers from a problem of flexion of the completed solar cell module after the epoxy resin is taken out of the mold. Further, in the technique of molding epoxy resin, the molding must be carried out while the mold is heated up to a high temperature of approximately 145-160° C. This causes a so-called bimetal phenomenon due to a difference in linear expansion coefficient between epoxy resin and a substrate, and when the solar cell module as a whole is cooled down to a normal temperature, the solar cell module gets flexed.

In order to deal with these problems, as the technique for sealing a solar cell element connected with a substrate by wire bonding, attention is paid to a technique for coating a solar cell element with a transparent adhesive sheet called an EVA (Ethylene Vinyl Acetate) sheet and laminate-sealing the solar cell element.

In general, the EVA sheet is used as a member for sealing a solar cell element in a solar cell module for housing. Since the technique using the EVA sheet does not require a mold, the technique can be carried out at low costs. Further, in the technique, a plurality of solar cell elements are coated with one EVA sheet with a large area and sealed together, and therefore the technique is suitable for, mass production. Further, since the technique using the EVA sheet does not require a mold, the technique prevents the problem of flexion of a completed solar cell module in the technique using a mold.

### Citation List

### [Patent Literature]

[Patent Literature 1] Japanese Patent Application Publication, Tokukaihei, No. 3-71660 A (Publication Date: Mar. 27, 1991)

[Patent Literature 2] Japanese Patent Application Publication, Tokukai, No. 2008-251929 A (Publication Date: Oct. 16, 2008)

### SUMMARY OF INVENTION

### Technical Problem

In the technique using the EVA sheet, a solar cell element 212 is connected with a substrate 213 via a bonding wire 211, and then the bonding wire 211 and the solar cell element 212 are coated with an EVA sheet 214, and the EVA sheet 214 is heated up to approximately 130° C. and fused while pressed, and the bonding wire 211 and the solar cell element 212 are laminate-sealed by ethylene vinyl acetate. Thus, a solar cell module 210 is produced as a commercial product. In the technique using the EVA sheet 214, when the bonding wire 211 and the solar cell element 212 are coated with the EVA sheet 214, a load derived from the weight of the EVA sheet 214 is applied to the bonding wire 211, and the load causes deformation of the bonding wire 211 (see FIG. 11). Deformation of a boding wire (wire) is hereinafter referred to as “wire sweep”.

The present invention was made in view of the foregoing problems. An object of the present invention is to provide a solar cell module which seals a solar cell element connected with a substrate by wire bonding and which is capable of preventing the wire sweep.

### Solution to Problem

In order to solve the foregoing problems, a solar cell module of the present invention is a solar cell module, including a substrate and a solar cell element connected with the substrate by wire, the wire being sealed with high viscosity resin so that a surface of the solar cell element, which surface is opposite to the substrate, is exposed.

With the arrangement, since the wire is sealed with resin, the wire is fixed (reinforced) by the resin. This reduces the possibility of the wire sweep due to a load applied to the wire. Therefore, the arrangement allows preventing the wire sweep.

Although not in the field of a solar cell module, Patent Literature 1 discloses a semiconductor device in which at least a connection between a pad of a semiconductor chip and a bonding wire is coated with reinforcing resin in order to prevent the wire sweep. In the semiconductor device disclosed in Patent Literature 1, resin merely made in a liquid form by heating epoxy resin is dropped onto the connection etc. to form the reinforcing resin. Such reinforcing resin wets and spreads over a surface of a semiconductor chip of a semiconductor device, in particular, an entire surface of the semiconductor chip opposite to a substrate. In fact, in any of the semiconductor devices disclosed in Patent Literature 1, the reinforcing resin wets and spreads over the entire surface.

If the reinforcing resin in Patent Literature 1 is applied to a solar cell module in which a solar cell element is connected with a substrate by wire, the reinforcing resin covers an entire surface of the solar cell element opposite to a substrate, and consequently light incident to the solar cell element is blocked by the reinforcing resin. This causes a possibility that the solar cell element, and therefore the solar cell module, has greatly reduced efficiency in power generation, or in a worst case, power generation gets impossible.

In order to deal with this problem, the solar cell module of the present invention employs high viscosity resin as resin for sealing and fixing a wire. When the high viscosity resin seals and fixes the wire, the high viscosity resin does not wet and spared over a surface of the solar cell element opposite to a substrate. This provides on the surface an exposed part which is not covered with the high viscosity resin, and therefore light incident to the solar cell element is not blocked. Consequently, the solar cell module of the present invention allows preventing the wire sweep without resulting in great dropping in the efficiency in power generation or in impossibility of power generation.

Therefore, since the solar cell module of the present invention is designed such that the wire is sealed by the high viscosity resin in order to expose the surface of the solar cell element opposite to the substrate, the solar cell module of the present invention is favorable for preventing the problem of wire sweep appearing in a solar cell module in which a solar cell element connected with a substrate by wire bonding is sealed.

In order to solve the foregoing problems, a method of the present invention for producing a solar cell module is a method for producing a solar cell module including a substrate and a solar cell element connected with the substrate by wire, the method comprising the steps of: sealing the wire with high viscosity resin so that a surface of the solar cell element, which surface is opposite to the substrate, is exposed, and coating the high viscosity resin and the solar cell element with a first sheet made of a transparent adhesive.

In the conventional art, a mold for coating by epoxy resin for sealing high viscosity resin and a solar cell element has been required. However, with the arrangement of the present invention, such mold is unnecessary. This allows production at low costs, and allows providing a solar cell module at a low price. Further, with the arrangement, a plurality of solar cell elements are coated with one first sheet with a large area and laminate-sealed together, and consequently a plurality of solar cell modules can be produced together. Thus, a solar cell module appropriate for mass production can be realized. In particular, use of an EVA sheet made of inexpensive ethylene vinyl acetate as the first sheet results in great reduction in the costs and the price of a solar cell module. When the solar cell module is coated with the first sheet, a load derived from the weight of the first sheet is applied to a wire. However, with the arrangement of the present invention, since the wire is fixed by high viscosity resin, it is possible to prevent the wire sweep.

In order to solve the foregoing problems, a method of the present invention for producing a solar cell module is a method for producing a solar cell module including a substrate and a solar cell element connected with the substrate by wire, the method comprising the steps of: coating the solar cell element with a first sheet made of a transparent adhesive, the first sheet having a thickness larger than a height of the wire as seen from the substrate, and the first sheet lacking a portion to coat the wire; and coating the first sheet with a second sheet which is transparent and has heat-resistance.

With the arrangement, since the first sheet lacks the portion to coat the wire, a load applied to the wire, which load is derived from the weight of the first sheet, can be reduced or eliminated. Consequently, the solar cell module of the present invention allows preventing the wire sweep even when the high viscosity resin is not used.

Further, with the arrangement, since the high viscosity resin is not used, it is possible to further downsize a part that may prevent light from being incident to the solar cell element. This allows further increasing the efficiency in power generation of the solar cell element.

It should be noted that in a case where the thickness of the first sheet is smaller than the height of the wire as seen from the substrate, when the first sheet coats the solar cell element, the wire protrudes above the first sheet. When the wire protrudes above the first sheet, coating the first sheet with the second sheet may cause the wire sweep because of a load applied to the wire which is derived from the weight of the second sheet. In order to prevent a load derived from the weight of the second sheet from being applied to the wire, it is necessary for the first sheet to have a thickness larger than the height of the wire as seen from the substrate.

### ADVANTAGEOUS EFFECTS OF INVENTION

As described above, the solar cell module of the present invention is a solar cell module, including a substrate and a solar cell element connected with the substrate by wire, the wire being sealed with high viscosity resin so that a surface of the solar cell element, which surface is opposite to the substrate, is exposed.

Further, the method of the present invention for producing a solar cell module is a method for producing a solar cell module including a substrate and a solar cell element connected with the substrate by wire, the method comprising the steps of: sealing the wire with high viscosity resin so that a surface of the solar cell element, which surface is opposite to the substrate, is exposed, and coating the high viscosity resin and the solar cell element with a first sheet made of a transparent adhesive.

Further, the method of the present invention for producing a solar cell module is a method for producing a solar cell module including a substrate and a solar cell element connected with the substrate by wire, the method comprising the steps of: coating the solar cell element with a first sheet made of a transparent adhesive, the first sheet having a thickness larger than a height of the wire as seen from the substrate, and the first sheet lacking a portion to coat the wire; and coating the first sheet with a second sheet which is transparent and has heat-resistance.

Consequently, in the solar cell module in which the solar cell element connected with the substrate by wire bonding is sealed, it is possible to prevent the wire sweep.

### BRIEF DESCRIPTION OF DRAWINGS

FIG. 1 is a cross sectional drawing showing a configuration of a solar cell module in accordance with one embodiment of the present invention. FIG. 1 also serves as a cross sectional drawing showing how to produce a solar cell module shown in FIG. 5, and showing the step of sealing a bonding wire with potting resin.

FIG. 2 is a cross sectional drawing showing how to produce the solar cell module shown in FIGS. 5 and 6, and showing the step of connecting a solar cell element with a substrate by wire bonding.

FIG. 3 is a cross sectional drawing showing how to produce the solar cell module shown in FIG. 5, and showing the step of coating the solar cell module shown in FIG. 1 with an EVA sheet and a PET sheet.

FIG. 4 is a cross sectional drawing showing how to produce the solar cell module shown in FIG. 5, and showing the step of thermocompressing the PET sheet shown in FIG. 3 against the substrate.

FIG. 5 is a cross sectional drawing showing a configuration of a solar cell module of the present invention which is completed as a commercial product.

FIG. 6 is a cross sectional drawing showing another configuration of a solar cell module of the present invention which is completed as a commercial product.

FIG. 7 is a perspective drawing showing a substrate connected with a solar cell element via a bonding wire, an EVA sheet, and a PET sheet in the solar cell module shown in FIG. 6.

FIG. 8 is a perspective drawing showing how to produce the solar cell module shown in FIG. 6, and showing the step of coating with the EVA sheet the FIG. 7 substrate connected with the solar cell element via the bonding wire.

FIG. 9 is a perspective drawing showing how to produce the solar cell module shown in FIG. 6 and showing the step of coating the EVA sheet in FIG. 8 with the PET sheet.

FIG. 10 is a perspective drawing showing how to produce the solar cell module shown in FIG. 6 and showing the step of thermocompressing the PET sheet in FIG. 9 against the substrate.

FIG. 11 is a cross sectional drawing showing a configuration of a conventional solar cell module.

### DESCRIPTION OF EMBODIMENTS

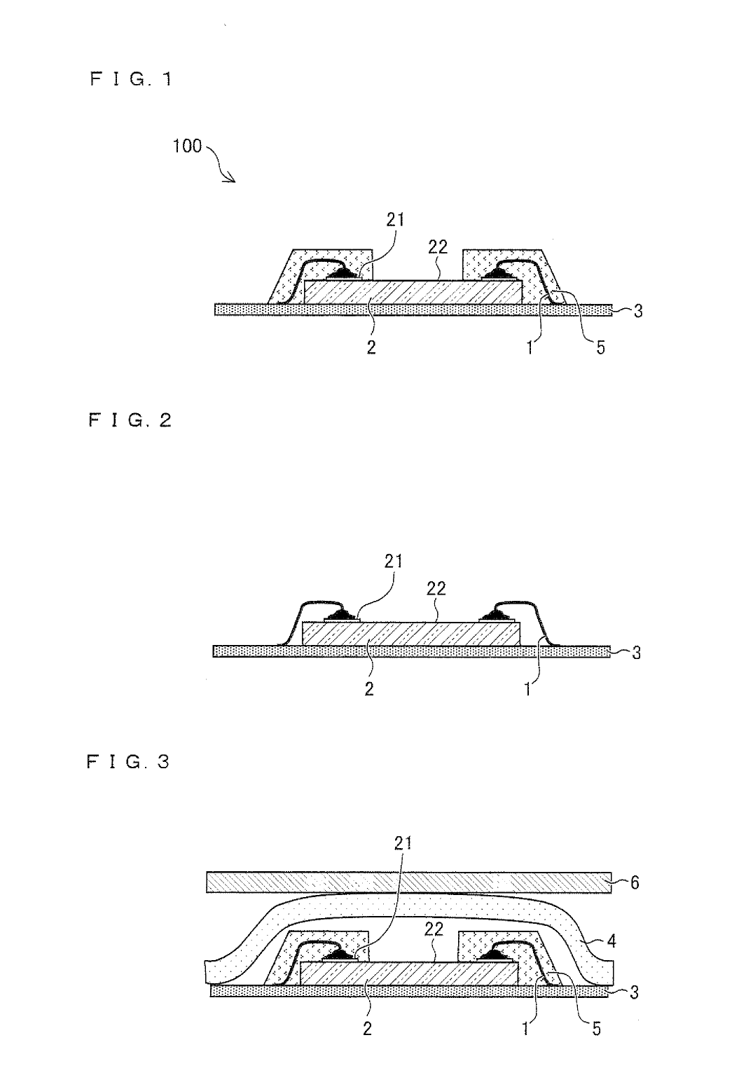

FIG. 1 is a cross sectional drawing showing a configuration of a solar cell module in accordance with one embodiment of the present invention.

A solar cell module 100 shown in FIG. 1 includes a bonding wire (wire) 1, a solar cell element 2, a substrate 3, and potting resin (high viscosity resin) 5.

The bonding wire 1 is a metal wire via which the solar cell element 2 is connected with the substrate 3 by well known wire bonding. One end of the bonding wire 1 is connected with the solar cell element 2 via a surface electrode 21 and the other end, of the bonding wire 1 is connected with an electrode (not shown) of the substrate 3. Thus, the solar cell element 2 is mounted on the substrate 3 via the bonding wire 1, and the solar cell element 2 and the substrate 3 are electrically connected with each other via the bonding wire 1. Examples of a material for the bonding wire 1 include gold, copper, and aluminum.

The solar cell element 2 is a semiconductor element that receives light such as a solar ray and converts light energy obtained from the light into electric energy by photoelectric transfer, allowing power generation in response to incident light (so-called photovoltaic generation). This element may be also referred to as a solar cell or merely a cell. Specifically, in the solar cell element 2, electrons (not shown) receive light energy, and convert the light energy into electric energy by a photovoltaic effect. An example of the solar cell element 2 is a silicon semiconductor such as a monocrystalline silicon and a polycrystalline silicon. Alternatively, a well known solar cell element may be used.

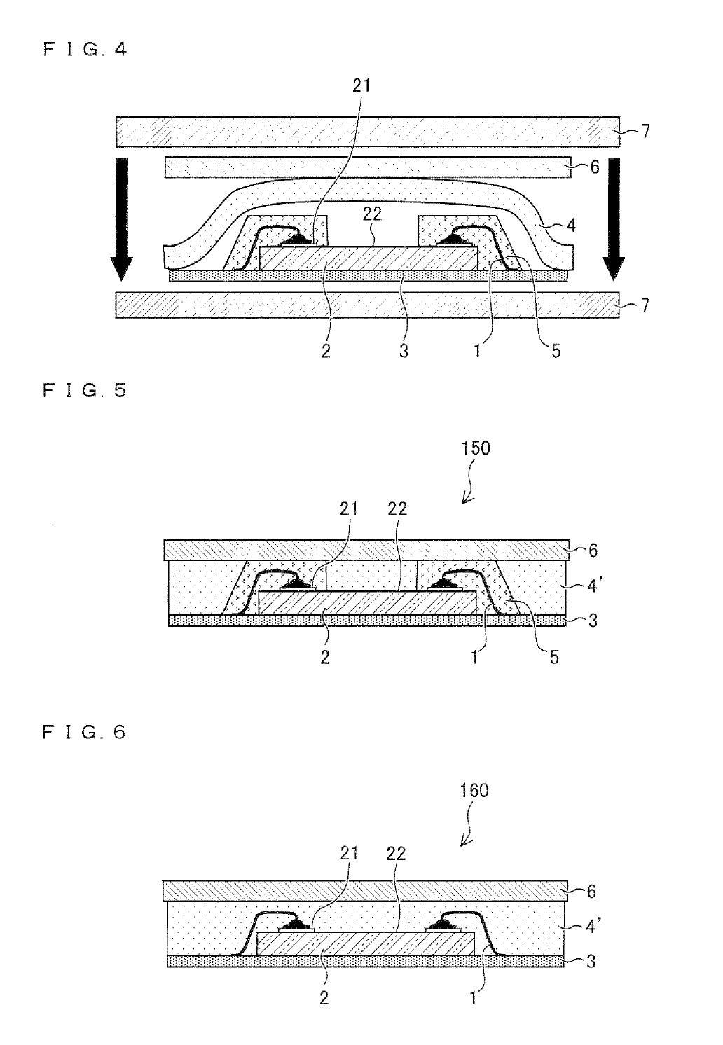

The substrate 3 is a substrate on which the solar cell element 2 is mounted. Examples of the substrate 3 include a glass substrate, a glass epoxy substrate, a polyimide substrate, and a polyvinyl substrate. The thickness of the substrate 3 is not particularly limited. However, considering that the substrate 3 requires a predetermined strength and weight, the thickness should range from approximately 0.1 to 30 mm in a case of a glass substrate. The substrate 3 may be made of plural materials, and may be covered with a metal film, a transparent conductive film, or an insulating film on its surface. It should be noted that since the substrate 3 is subjected to direct thermocompression by pressing a heater 7 (see FIG. 4) against the substrate 3 in the step of producing a solar cell module 150 (see FIG. 5) as a commercial product, it is desirable that the substrate 3 has a heat-resistance to some extent, e.g. a heat-resistance up to approximately 200° C.

Although not shown in the drawing, a backside electrode is further provided between the solar cell element 2 and the substrate 3, and the solar cell element 2 and the substrate 3 are electrically connected with each other via the backside electrode.

The potting resin 5 is resin preferably used for potting. An example of the potting resin 5 is epoxy resin. The potting resin 5 coats the bonding wire 1 in such a manner that the potting resin 5 covers substantially all of the bonding wire 1, thereby selectively sealing at least the bonding wire 1. That is, the potting resin 5 partially seals the solar cell module 100 by sealing substantially all of the bonding wire 1. The sealing of the bonding wire 1 by the potting resin 5 fixes (reinforces) the bonding wire 1. Since the bonding wire 1 is fixed by the potting resin 5, it is possible to reduce the possibility that the load applied to the bonding wire 1 causes the wire sweep. Therefore, with the above arrangement, it is possible to prevent the wire sweep of the bonding wire 1.

The potting resin 5 used here is so-called high viscosity resin whose viscosity ranges, for example, from 5 to 500 Pa·s when the temperature of the resin is 25° C. The following explains why the high viscosity resin is used as the potting resin 5.

If the potting resin 5 in the solar cell module 100 is so-called low viscosity resin whose viscosity is less than 5 Pa·s (when the temperature of the resin is 25° C.), the potting resin 5 wets and spreads over the whole of a surface 22 that is a surface of the solar cell element 2 opposite to the substrate 3 (a surface of the solar cell element 2 which is positioned upward in FIG. 1), covering the whole of the surface 22. Consequently, light incident to the solar cell element 2 is blocked by the potting resin 5, resulting in great reduction in light energy supplied to the solar cell element 2. In a worst case, the solar cell element 2 cannot receive light energy at all. Consequently, in the solar cell element 2, and therefore in the solar cell module 100, efficiency in power generation drops greatly, or in a worst case, power generation gets impossible.

An example of a technique for preventing the potting resin 5 from wetting and spreading over the whole of the surface 22 while low viscosity resin is used as the potting resin 5 in the solar cell module 100 is a technique for forming a protrusion (protrusive electrode; not shown) made of silver paste for example on the surface 22 in order to prevent flow of the potting resin 5. However, when the technique is used, the formed protrusion covers the surface 22, and the protrusion blocks light incident to the solar cell element 2. Consequently, light energy supplied to the solar cell element 2 drops greatly (efficiency in power generation drops greatly), and in a worst case, the solar cell element 2 cannot receive light energy (cannot generate power).

On the other hand, if the potting resin 5 in the solar cell module 100 is high viscosity resin, the potting resin 5 does not wet and spread over the whole of the surface 22, depending on the degree of viscosity of the high viscosity resin. Consequently, the potting resin 5 with high viscosity is advantageous in that it can be selectively provided on a desired part of the surface 22. In the solar cell module 100, with use of the advantage of the potting resin 5 with high viscosity, the potting resin 5 is provided in such a manner as to selectively seal the bonding wire 1. This allows the whole of the surface 22 to have a sufficiently broad exposed area that is not covered with the potting resin 5. This prevents blocking of light incident to the solar cell element 2. Consequently, in the solar cell module 100, it is possible to prevent the wire sweep of the bonding wire 1 without resulting in great drop in the efficiency in power generation or in total impossibility of power generation.

Therefore, since the solar cell module 100 is designed such that the bonding wire 1 is sealed by the potting resin 5 with high viscosity in order to expose the surface 22 of the solar cell element 2 opposite to the substrate 3, the solar cell module 100 is favorable for preventing the problem of wire sweep appearing in a solar cell module in which a solar cell element connected with a substrate by wire bonding is sealed.

Further, as detailed later, the potting resin 5 with high viscosity has a function of preventing an excessive pressure from being applied to the solar cell module when the solar cell module is subjected to thermocompression in the step of producing a solar cell module 150 (see FIG. 5), and a function of protecting the bonding wire 1 from a pressure which is caused depending on a thermal cycle of the solar cell module.

As shown in FIG. 1, the potting resin 5 may further seal the vicinity of the bonding wire 1. This allows further solidly fixing the bonding wire 1. However, it should be noted that in a case where the potting resin 5 further seals the vicinity of the bonding wire 1 and thus covers the surface 22 of the solar cell element 2, if the potting resin 5 covers a larger part of the surface 22, light incident to the solar cell element 2 is more blocked by the potting resin 5, resulting in drop of the efficiency in power generation. As long as the above is noted, what part is covered by the potting resin 5 is not particularly limited, provided that the potting resin 5 covers substantially the whole of the bonding wire 1.

It is favorable that the potting resin 5 is designed such that the potting resin 5 has a viscosity ranging from 5 to 500 Pa·s when the temperature thereof is 25° C.

If the potting resin 5 is designed such that the potting resin 5 has a viscosity of less than 5 Pa·s when the temperature thereof is 25° C., the potting resin 5 wets and spreads over the solar cell element 2 and thus covers the whole of the surface 22 of the solar cell element 2 which surface 22 is opposite to the substrate 3. Consequently, light incident to the solar cell element 2 is blocked by the potting resin 5. As a result, in the solar cell module 100, light energy supplied to the solar cell element 2 drops greatly, or in a worst case, the solar cell element 2 cannot receive light energy. Consequently, in the solar cell element 2, and therefore in the solar cell module 100, the efficiency in power generation drops greatly, or in a worst case, power generation gets impossible. Further, when the bonding wire 1 is sealed by the potting resin 5 having a viscosity of less than 5 Pa·s, the bonding wire 1 is fixed less solidly by the potting resin 5 and the bonding wire 1 cannot have a sufficient strength against the load, resulting in a possibility of the wire sweep of the bonding wire 1.

In contrast thereto, if the potting resin 5 is designed such that the potting resin 5 has a viscosity of more than 500 Pa·s when the temperature thereof is 25° C., the potting resin 5 is very difficult to wet and spread, which makes insufficient filling of the potting resin 5 into gaps between the solar cell element 2 and the bonding wire 1, and the insufficient filling may cause spaces. This may result in decrease in the quality and reliability of the solar cell module 150 (see FIG. 5).

In view of the above, the potting resin 5 is preferably designed such that the potting resin 5 has a viscosity ranging from 5 to 500 Pa·s when the temperature thereof is 25° C.

Further, the potting resin 5 is preferably transparent high viscosity resin. When the potting resin 5 is transparent, light is incident to the solar cell element 2 via the potting resin 5. This allows preventing the blocking of light incident to the solar cell element 2 by the potting resin 5.

When the potting resin 5 is transparent, the solar cell element 2 can generate power also at a part covered with the potting resin 5. Accordingly, in this case, an exposed part of the surface 22 may be small, or the exposed part of the surface 22 do not have to exist at all. In this case, the solar cell module 100 may be designed such that the exposed surface 22 of the solar cell element 2 is covered with the transparent potting resin 5. This broadens a portion sealed by the potting resin 5, allowing the potting resin 5 to further solidly fix the bonding wire 1, further effectively preventing the wire sweep. In this case, since it is unnecessary to secure an exposed part of the surface 22, the potting resin 5 do not necessarily have to be high viscosity resin.

As a method for producing a solar cell module in accordance with one embodiment of the present invention, the following explains steps of producing the solar cell module 150 (see FIG. 5) from the solar cell module 100 shown in FIG. 1, with reference to FIGS. 2-5.

Initially, in the step shown in FIG. 2, the solar cell element 2 is connected with the substrate 3 by well known wire bonding using the bonding wire 1. That is, in the step shown in FIG. 2, as a preparation for producing the solar cell module 100 shown in FIG. 1, one end of the bonding wire 1 is connected with the solar cell element 2 via the surface electrode 21, and the other end of the bonding wire 1 is connected with an electrode (not shown) of the substrate 3.

Then, the bonding wire 1 is covered with the potting resin 5 by well known potting, and is sealed by the potting resin 5. Thus, the surface 22 of the solar cell element 2 is exposed to produce the solar cell module 100 (see FIG. 1).

Then, in the step shown in FIG. 3, the solar cell element 2 and the potting resin 5 sealing the bonding wire 1 in the solar cell module 100 are coated with the EVA sheet (first sheet) 4.

When the solar cell element 2 and the potting resin 5 sealing the bonding wire 1 are laminate-sealed by the EVA sheet 4, it is unnecessary to use a mold for coating epoxy resin which is required in sealing in the conventional art. This allows production at low costs, allowing the solar cell module 150 (see FIG. 5) to be sold at a low price. Further, in this case, it is possible to produce a plurality of solar cell modules 150 together by coating not only the solar cell element 2 but also other solar cell elements (not shown in the drawing) with one EVA sheet 4 and laminate-sealing them together. Therefore, this method is favorable for mass production. In particular, when the EVA sheet 4 made of inexpensive ethylene vinyl acetate is used in laminate-sealing, it is possible to greatly reduce costs and therefore reduce the price of the solar cell module 150. Further, since the EVA sheet 4 has lower elasticity, extremely higher flexibility, and lower laminate temperature (mentioned later) than epoxy resin used in the sealing in the conventional art using a mold, it is possible to realize the solar cell module 150 with extremely small flexion.

When the solar cell module 100 (see FIG. 1) is coated with the EVA sheet 4, a load derived from the weight of the EVA sheet 4 is applied to the bonding wire 1. However, since the bonding wire 1 is fixed by the potting resin 5, it is possible to prevent the wire sweep of the bonding wire 1.

The EVA sheet 4 has low elasticity and extremely high flexibility. Consequently, when the solar cell module 150 (see FIG. 5) is subjected to a thermal cycle of repeating cooling down to approximately −30° C. and heating up to approximately 100° C., the EVA sheet 4 is stretched greatly. When the EVA sheet 4 is stretched greatly, an unexpectedly great pressure is applied to the bonding wire 1, which may break the bonding wire 1. However, since the bonding wire 1 is sealed and fixed by the potting resin 5, it is possible to prevent the breakage of the bonding wire 1. That is, the sealing of the bonding wire 1 by the potting resin 5 protects the bonding wire 1 in the thermal cycle. In particular, when the potting resin 5 has low linear expansion coefficient and high elasticity, the potting resin 5 can further effectively protect the bonding wire 1 in the thermal cycle.

The EVA sheet 4 may be replaced with a transparent adhesive sheet made of a material such as PBT (Polybutylene terephthalate), an acrylic material, and a silicone material.

Further, in the step shown in FIG. 3, the EVA sheet 4 is coated with a PET sheet (second sheet) 6 made of PET (Polyethylene Terephthalate).

The PET sheet 6 is transparent and has a heat-resistance against heat applied to the PET sheet 6 when the PET sheet 6 is subjected to thermocompression by the heater 7 (see FIG. 4) (in other words, a heat-resistance against heat of approximately 200° C.). The PET sheet 6 may be replaced with a polyethylene sheet. Functions of the PET sheet 6 will be explained later.

Then, in the step shown in FIG. 4, by the heater 7 used in thermopress for thermocompression, the EVA sheet 4 is heated up to approximately 130° C. and fused and at the same time the PET sheet 6 is pressed to the substrate 3 and subjected to thermocompression, so that laminate-sealing is carried out using ethylene vinyl acetate 4′ (see FIG. 5) and the PET sheet 6.

Since the EVA sheet 4 is a sheet made of ethylene vinyl acetate that is a transparent adhesive, when the EVA sheet 4 is subjected to thermocompression and fused, there is a possibility that the ethylene vinyl acetate 4′ (see FIG. 5) that is a transparent adhesive attaches to the heater 7. In order to avoid this possibility, the EVA sheet 4 is coated with the PET sheet 6.

Since the EVA sheet 4 is coated with the PET sheet 6, thermocompression is carried out to the PET sheet 6 having no possibility of being fused by heat of the thermocompression and attaching to the heater 7. This solves the problem that the ethylene vinyl acetate 4′ (see FIG. 5) attaches to the heater 7 when the EVA sheet 4 is fused.

In the solar cell module in the step shown in FIG. 4, if an excessive pressure is applied by the heater 7 to the solar cell module because of an excessive load of the heater 7 in thermocompression, the ethylene vinyl acetate 4′ (see FIG. 5) spreads over a wide range of the substrate 3 when the EVA sheet 4 is fused. The ethylene vinyl acetate 4′ thus spread applies a pressure to the bonding wire 1, and this pressure may cause the wire sweep of the bonding wire 1. However, by sealing and fixing the bonding wire 1 by the potting resin 5 with high viscosity, the potting resin 5 prevents the heater 7 from going toward the substrate 3, preventing the load of the heater 7 from being excessive in the thermocompression and thus preventing the heater 7 from applying an excessive pressure. Further, by designing individual potting resins 5 to have the same height seen from the substrate 3, it is possible to keep the heater 7 horizontally with respect to the substrate 3, allowing the solar cell module 150 to have an even thickness.

The solar cell module having been subjected to laminate-sealing is the solar cell module 150 shown in FIG. 5 which is a commercial product. The EVA sheet 4 has been fused and changed into the ethylene vinyl acetate 4′, which fills gaps between the substrate 3 and the PET sheet 6 and serves as an adhesive. The solar cell element 2 and the potting resin 5 sealing the bonding wire 1 are sealed by the ethylene vinyl acetate 4′.

As described above, the potting resin 5 with high viscosity is epoxy resin for example. In a case where the solar cell module of the present invention is applied to an electronic apparatus including a liquid crystal display, the epoxy resin may be the same as sealing resin used in a driving device of the liquid crystal display.

FIG. 6 is a cross sectional drawing showing a configuration of a solar cell module in accordance with another embodiment of the present invention.

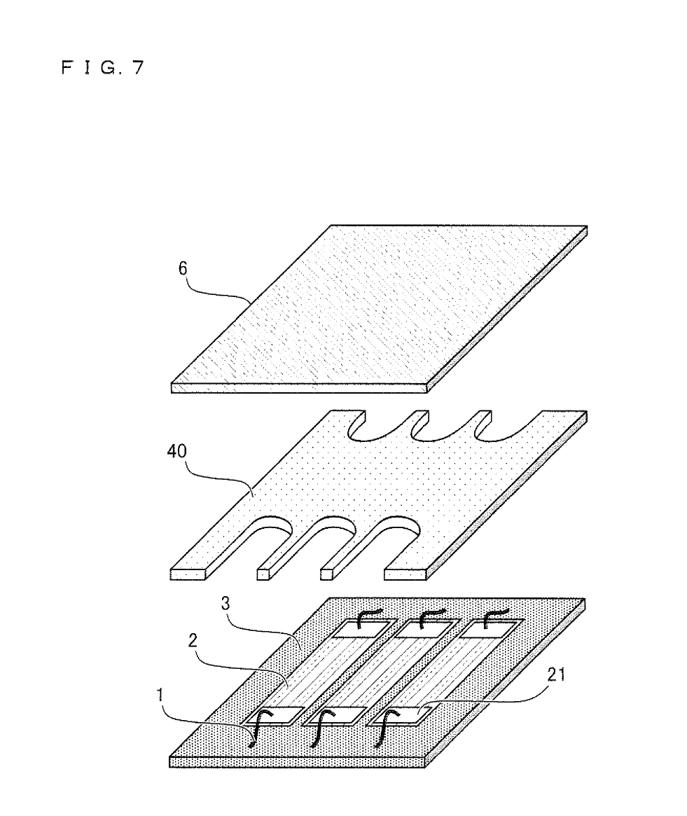

A solar cell module 160 shown in FIG. 6 is different from the solar cell module 150 shown in FIG. 5 in that the solar cell module 160 does not include the potting resin 5. Further, as shown in FIG. 7, an EVA sheet 40 made of the ethylene vinyl acetate 4′ is different from the EVA sheet 4 (see FIG. 5) in that the EVA sheet 40 lacks a portion to coat the bonding wire 1. That is, the EVA sheet 40 is obtained by arranging the EVA sheet 4 to exclude in advance a portion which exists above the bonding wire 1 as seen from the substrate 3 when the solar cell element 2 etc. is coated with the EVA sheet 4 (see FIG. 3).

The EVA sheet 40 is designed to have a thickness larger than the height of the bonding wire 1 as seen from the substrate 3, i.e., the height of the bonding wire 1 in a direction perpendicular to a surface of the substrate 3 closer to the solar cell element 2. Consequently, when the EVA sheet 40 coats the solar cell element 2 etc., an upper part of the EVA sheet 40 is positioned above an upper part of the bonding wire 1. Since the thickness of the EVA sheet 40 is set to range from 0.1 to 1.0 mm according to a standard, there is a case where the thickness cannot be freely changed. In a case where the thickness of the EVA sheet 40 cannot be freely changed, the height of the bonding wire 1 as seen from the substrate 3 should be made smaller so that the thickness of the EVA sheet 40 is larger than the height of the bonding wire 1 as seen from the substrate 3.

Since the EVA sheet 40 lacks the portion to coat the bonding wire 1, there is no load applied to the bonding wire 1 which is derived from the weight of the EVA sheet 40. Consequently, in the solar cell module 160, even when the potting resin 5 (see FIG. 1 etc.) is not used, it is possible to prevent the wire sweep.

Further, since the potting resin 5 (see FIG. 1 etc.) is not used in the solar cell module 160, a region which is likely to prevent light from being incident to the solar cell element 2 is further downsized, allowing the solar cell element 2 to have further higher efficiency in power generation.

It should be noted that in a case where the thickness of the EVA sheet 40 is smaller than the height of the bonding wire 1 as seen from the substrate 3, when the EVA sheet 40 coats the solar cell element 2, the bonding wire 1 protrudes above the EVA sheet 40 as seen from the substrate 3. When the bonding wire 1 protrudes above the EVA sheet 40, coating the EVA sheet 40 with the PET sheet 6 may cause the wire sweep of the bonding wire 1 because of a load applied to the bonding wire 1 which is derived from the weight of the PET sheet 6. In order to prevent a load derived from the weight of the PET sheet 6 from being applied to the bonding wire 1, it is necessary for the EVA sheet 40 to have a thickness larger than the height of the bonding wire 1 as seen from the substrate 3.

In order to realize the EVA sheet 40, it is necessary to exclude in advance a portion of the EVA sheet 4 which portion exists above the bonding wire 1 as seen from the substrate 3 when the solar cell element 2 etc. is coated with the EVA sheet 4. For this exclusion, it is desirable to cut out the portion to be excluded, as shown in FIG. 7. Alternatively, the EVA sheet 40 may be realized by making a concavity (not shown) in the portion-to-be-excluded of the EVA sheet 4 in order that the EVA sheet 4 does not touch the bonding wire 1 when the solar cell element 2 etc. is coated with the EVA sheet 4. That is, the EVA sheet 40 should be designed such that the EVA sheet 40 does not touch the bonding wire 1 when the solar cell element 2 etc. is coated with the EVA sheet 40.

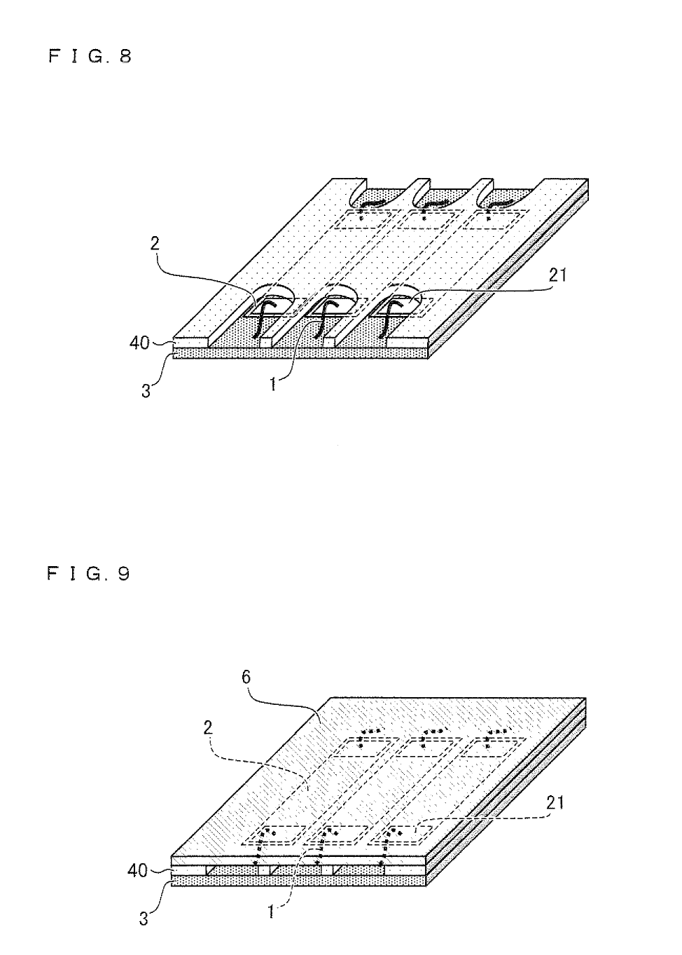

As a method for producing the solar cell module in accordance with another embodiment of the present invention, the following explains steps of producing the solar cell module 160 (see FIG. 6) with reference to FIGS. 8-10.

Initially, as in the step shown in FIG. 2, one end of the bonding wire 1 is connected with the solar cell element 2 via the surface electrode 21 and the other end of the bonding wire 1 is connected with an electrode (not shown) of the substrate 3. Thus, the solar cell element 2 is connected with the substrate 3 by well known wire bonding using the bonding wire 1.

In the step shown in FIG. 8, the solar cell element 2 is coated with the EVA sheet 40. Here, in order that the EVA sheet 40 does not touch the bonding wire 1 from the above as seen from the substrate 3, the bonding wire 1 is overlapped with a space obtained by excluding a portion from the EVA sheet 40 in advance. That is, in the step, the solar cell element 2 is coated with the EVA sheet 40 in such a manner that the bonding wire 1 is not coated with the EVA sheet 40.

In the step shown in FIG. 9, the EVA sheet 40 is coated with the PET sheet 6. Since the thickness of the EVA sheet 40 is larger than the height of the bonding wire 1 as seen from the substrate 3, when the EVA sheet 40 is coated with the PET sheet 6, the EVA sheet 40 prevents the PET sheet 6 from going toward the substrate 3. Consequently, the PET sheet 6 does not touch the bonding wire 1, so that a load derived from the weight of the PET sheet 6 is not applied to the bonding wire 1.

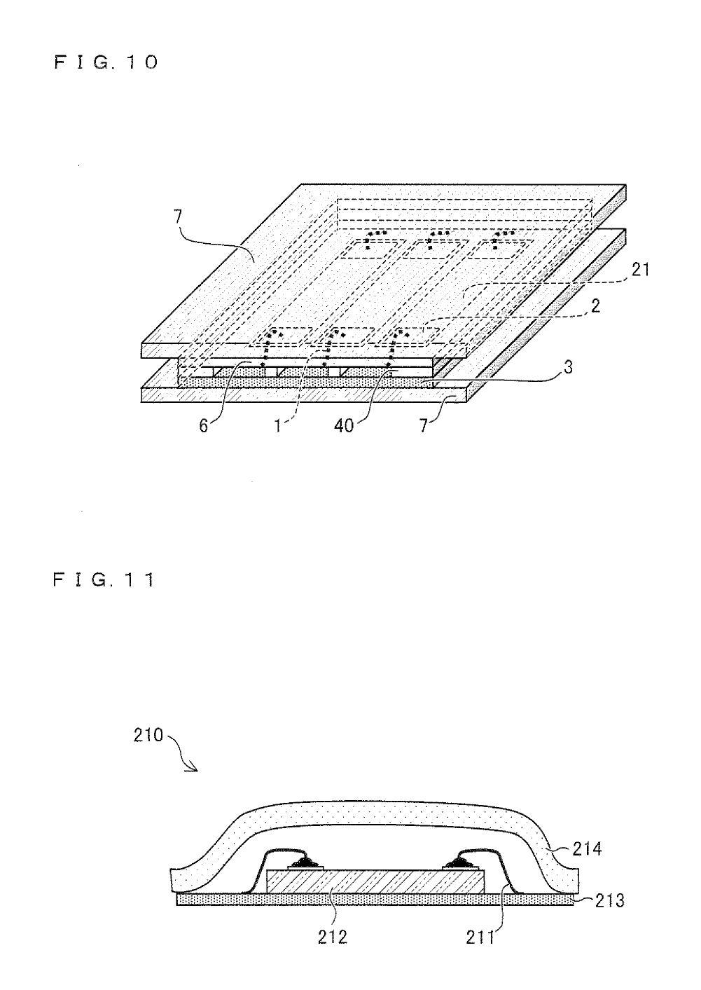

In the step shown in FIG. 10, by the heater 7, the EVA sheet 40 is heated up to approximately 130° C. and fused and at the same time the PET sheet 6 is pressed to the substrate 3 and subjected to thermocompression, so that laminate-sealing is carried out using the ethylene vinyl acetate 4′ (see FIG. 6) and the PET sheet 6. Since the EVA sheet 40 is coated with the PET sheet 6, thermocompression is carried out to the PET sheet 6 having no possibility of attaching to the heater 7. This solves the problem that the transparent adhesive attaches to the heater 7 when the EVA sheet 40 is fused.

The solar cell module having been subjected to laminate-sealing is the solar cell module 160 shown in FIG. 6 which is a commercial product. The EVA sheet 40 has been fused and changed into the ethylene vinyl acetate 4′, which fills gaps between the substrate 3 and the PET sheet 6 and serves as an adhesive. The bonding wire 1 and the solar cell element 2 are sealed by the ethylene vinyl acetate 4′.

Needless to say, the solar cell module 160 may be further provided with the potting resin 5 (see FIG. 1 etc.). Further providing the solar cell module 160 with the potting resin 5 increases the effect of preventing the wire sweep of the bonding wire 1 and the effect of protecting the bonding wire 1 in the thermal cycle. However, there is a possibility that the efficiency in power generation by the solar cell element 2 drops a little. Therefore, if the effect of protecting the bonding wire 1 in the thermal cycle is secured as desired without providing the potting resin 5, it is more favorable to use the solar cell module 160 shown in FIG. 6 in which the potting resin 5 is not used.

The heater 7 is preferably a well known heater used for producing a solar cell module for housing. Since the heater used for producing a solar cell module for housing has a very broad area capable of thermocompression, the heater is preferably used in mass production of a solar cell module, and makes it unnecessary to use other heaters. Consequently, it is possible to further reduce costs.

Mass production of the solar cell module of the present invention is carried out as follows: specifically, a plurality of solar cell elements are coated with one EVA sheet, and if necessary, the EVA sheet is coated with a PET sheet. The PET sheet coating the EVA sheet (the EVA sheet in case of not using the PET sheet) is thermocompressed against a substrate so that the plurality of solar cell elements are sealed. Then, the resultant is divided into pieces so that one piece includes one solar cell element, and thus each piece is regarded as a solar cell module. The mass production of the solar cell module of the present invention is carried out in this manner.

In the solar cell module of the present invention, instead of sealing the solar cell element with the EVA sheet, the solar cell element may be sealed by applying a transparent silicon material in a liquid form to the solar cell element and attaching a glass to the solar cell element.

The present invention is not limited to the description of the embodiments above, but may be altered by a skilled person within the scope of the claims. An embodiment based on a proper combination of technical means disclosed in different embodiments is encompassed in the technical scope of the present invention.

Specifically, in the solar cell module of the present invention, the high viscosity resin is preferably designed such that when the temperature of the high viscosity resin is 25° C., the viscosity of the high viscosity resin ranges from 5 to 500 Pa·s. “Pa·s” indicates “Pascal second” that is a unit indicative of viscosity in the International System of Units.

If the high viscosity resin is designed such that the high viscosity resin has a viscosity of less than 5 Pa·s when the temperature thereof is 25° C., the high viscosity resin wets and spreads over the solar cell element and thus covers the whole of the surface of the solar cell element which surface is opposite to the substrate. Consequently, light incident to the solar cell element is blocked by the high viscosity resin. As a result, in the solar cell module, light energy supplied to the solar cell element drops greatly, or in a worst case, the solar cell element cannot receive light energy. Consequently, in the solar cell element, and therefore in the solar cell module, the efficiency in power generation drops greatly, or in a worst case, power generation gets impossible. Further, when the bonding wire is sealed by the high viscosity resin having a viscosity of less than 5 Pa·s when the temperature thereof is 25° C., the bonding wire is fixed less solidly by the high viscosity resin and the bonding wire cannot have a sufficient strength against the load, resulting in a possibility of the wire sweep of the bonding wire when the load is applied to the bonding wire.

In contrast thereto, if the high viscosity resin is designed such that the high viscosity resin has a viscosity of more than 500 Pa·s when the temperature thereof is 25° C., the high viscosity resin is very difficult to flow, which makes insufficient filling of the high viscosity resin into gaps between the solar cell element and the bonding wire, and the insufficient filling may cause spaces. This may result in decrease in the quality and reliability of the solar cell module.

In view of the above, the high viscosity resin is preferably designed such that the high viscosity resin has a viscosity ranging from 5 to 500 Pa·s when the temperature thereof is 25° C.

The solar cell module of the present invention is obtained by coating the high viscosity resin and the solar cell element with a first seat made of a transparent adhesive. In particular, the first sheet is preferably made of ethylene vinyl acetate.

Since the first sheet is made of a transparent adhesive, when the first sheet is subjected to thermocompression and is fused, there is a possibility that the transparent adhesive constituting the first sheet attaches to a device for thermocompression (e.g. heater).

In order to deal with this problem, the solar cell module of the present invention is obtained by coating the first sheet with a second sheet that is transparent and has a predetermined heat-resistance.

The method of the present invention for producing a solar cell module includes the steps of coating the first sheet with a second sheet that is transparent and has a predetermined heat-resistance and thermocompressing the second sheet against the substrate.

With the arrangement, the first sheet is coated with the transparent second sheet having a predetermined heat-resistance, specifically, a heat-resistance against heat applied by the device in the thermocompression. Consequently, thermocompression is carried out to the second sheet having no possibility of being fused by heat of the thermocompression and attaching to the device. This solves the problem that the transparent adhesive attaches to the device when the first sheet is fused.

In the solar cell module of the present invention, the high viscosity resin is transparent.

With the arrangement, the high viscosity resin is transparent. This prevents the high viscosity resin from blocking light incident to the solar cell element.

Further, in a case where the first sheet lacks a portion to coat the wire, coating the first sheet with the second sheet and thermocompressing the second sheet against the substrate solves the problem that the transparent adhesive attaches to the device when the first sheet is fused.

### INDUSTRIAL APPLICABILITY

The present invention provides a solar cell module capable of preventing the wire sweep. Accordingly, the present invention is preferably applicable to a solar cell module in which a solar cell element connected with a substrate by wire bonding is sealed and to various devices including the solar cell module.

### REFERENCE SIGNS LIST

1. Bonding wire (wire)
2. Solar cell element
3. Substrate
4, 40. EVA sheet (first sheet)
4′. Ethylene vinyl acetate
5. Potting resin (high viscosity resin)
6. PET sheet (second sheet)
22. Surface of solar cell element
100, 150, 160. Solar cell module

1. A solar cell module, including a substrate and a solar cell element connected with the substrate by wire,
the wire being sealed with high viscosity resin so that a surface of the solar cell element, which surface is opposite to the substrate, is exposed.

2. The solar cell module as set forth in claim 1, the solar cell module being obtained by coating the high viscosity resin and the solar cell element with a first sheet made of a transparent adhesive.

3. The solar cell module as set forth in claim 2, the solar cell module being obtained by coating the first sheet with a second sheet which is transparent and has predetermined heat-resistance.

4. The solar cell module as set forth in claim 1, wherein when a temperature of the high viscosity resin is 25° C., the high viscosity resin has viscosity ranging from 5 to 500 Pa·s.

5. The solar cell module as set forth in claim 1, wherein the high viscosity resin is transparent.

6. The solar cell module as set forth in claim 2, wherein the first sheet is made of ethylene vinyl acetate.

7. A method for producing a solar cell module including a substrate and a solar cell element connected with the substrate by wire,
the method comprising the steps of:
sealing the wire with high viscosity resin so that a surface of the solar cell element, which surface is opposite to the substrate, is exposed, and
coating the high viscosity resin and the solar cell element with a first sheet made of a transparent adhesive.

8. The method as set forth in claim 7, further comprising the steps of:
coating the first sheet with a second sheet which is transparent and has predetermined heat-resistance, and
thermocompressing the second sheet against the substrate.

9. A method for producing a solar cell module including a substrate and a solar cell element connected with the substrate by wire,
the method comprising the steps of:
coating the solar cell element with a first sheet made of a transparent adhesive, the first sheet having a thickness larger than a height of the wire as seen from the substrate, and the first sheet lacking a portion to coat the wire; and
coating the first sheet with a second sheet which is transparent and has heat-resistance.

10. The method as set forth in claim 9, further comprising the step of thermocompressing the second sheet against the substrate.
